(19) United States
(12) Patent Application Publication
(10) Pub. No.: US 2022/0329034 A1
(43) Pub. Date: Oct. 13, 2022

(54) ULTRA-COMPACT HIGH POWER FIBER PUMP MODULE

(71) Applicant: LEONARDO ELECTRONICS US INC., Tucson, AZ (US)

(72) Inventor: Hans-Georg TREUSCH, Tucson, AZ (US)

(21) Appl. No.: 17/719,210

(22) Filed: Apr. 12, 2022

Related U.S. Application Data
(60) Provisional application No. 63/173,971, filed on Apr. 12, 2021.

(51) Int. Cl. H01S 3/04; H01S 3/067

(52) U.S. Cl. CPC H01S 3/0405; H01S 3/06758; H01S 3/06704

(57) ABSTRACT

An ultra-compact, high power, fiber pump module apparatus has a heatsink with a stepped outer shape. The heatsink has at least one interior cooling channel. A plurality of single emitter diodes is positioned on one step of the stepped outer shape of the heatsink, respectively. At least two beam-shifting structures are positioned in a beam path of each of the plurality of single emitter diodes. The at least two beam-shifting structures fold each beam emitted from the plurality of single emitter diodes in at least three dimensions. At least one beam combining structure is positioned in the beam path, wherein the at least one beam combining structure combines the beams from each of the plurality of single emitter diodes into a single, combined beam. The single, combined beam is output from the ultra-compact, high power, fiber pump module apparatus.

### CROSS REFERENCE TO RELATED APPLICATION

This application claims benefit of U.S. Provisional Application Ser. No. 63/173,971 entitled, “Ultra-Compact High Power Fiber Pump Module” filed Apr. 12, 2021, the entire disclosure of which is incorporated herein by reference.

### FIELD OF THE DISCLOSURE

The present disclosure is generally related to laser modules and more particularly is related to an ultra-compact high power fiber pump module.

### BACKGROUND OF THE DISCLOSURE

Single emitter-based fiber pump modules offer the highest coupling and overall efficiency compared to approaches using multiple emitters on a semiconductor chip. Single emitters utilize one emission area per laser diode, whereas a laser diode bar can have a number of emitters next to one another in a single structure. With single emitter pump modules, the heat generated from the lasers is spread out over a specific area and the device can be contact cooled to a water-cooled platform.

FIG. 1 is an illustration of a layout of a single emitter pump module 10 in accordance with the prior art. As can be seen in FIG. 1, a conventional single emitter pump module 10 includes a plurality of single emitters 20 or single laser diodes positioned on one side of the module 10. The light path from each of the single emitters 20 travels through a corresponding lens 30, and then to a corresponding mirror 40. The light then enters a beam-combining structure 50, such as a polarization prism. The light then travels through various lenses 60 and is directed into a fiber optic cable 70. FIG. 2 is an illustration of a light path diagram showing the path of the light in the conventional module 10, from the single emitters 20, through the corresponding lens 30 and mirrors 40, being combined within the polarization prism 50, and then directed through additional lenses 60 and into the optical fiber 70.

While the layout of the various components can be changed or rearranged, all conventional modules 10 include the components on a single plane, such that the light path between the various components occurs in only two dimensions, e.g., along the length and width of the module 10. This single plane design is due to the fact that the module 10 is cooled through conduction from the bottom of the module 10. Specifically, conduction cooling may be achieved through a water channel through the module 10 below the components. For example, the water channel may be formed in the module base 12, which is positioned below the emitters 20, the lenses 30, mirrors 40, prisms 50, and additional lenses 60.

Historically, conventional pump modules with single emitters have achieved coupling efficiencies generally between 85% and 93% which is often satisfactory. However, these efficiencies are limited by power per emitted, and ultimately the total power to the module, which is always under 400W, and more commonly well under 200W. In contrast, conventional modules with multiple-emitter bars (not single emitters), can achieve greater total power than single emitter modules, but they can only achieve a coupling efficiency of approximately 80%. No conventional module is capable of achieving powers which exceed approximately 400W and which provide coupling efficiencies which are above 85%.

Thus, a heretofore unaddressed need exists in the industry to address the aforementioned deficiencies and inadequacies.

### SUMMARY OF THE DISCLOSURE

Embodiments of the present disclosure provide an ultra-compact, high power, fiber pump module apparatus, and related systems and methods. Briefly described, in architecture, one embodiment of the apparatus, among others, can be implemented as follows. A heatsink has a stepped outer shape and at least one interior cooling channel. At least one single emitter diode is positioned on one step of the stepped outer shape of the heatsink. At least two beam-shifting structures are positioned in a beam path of the at least one single emitter diode, the at least two beam-shifting structures folding a beam emitted from the at least one single emitter diode in at least three dimensions. At least one output is provided, from which the beam is output from the ultra-compact, high power, fiber pump module apparatus.

The present disclosure can also be viewed as providing an ultra-compact, high power, fiber pump module apparatus. Briefly described, in architecture, one embodiment of the apparatus, among others, can be implemented as follows. A heatsink has a stepped outer shape and at least one interior cooling channel. A plurality of single emitter diodes is provided, with each positioned on one step of the stepped outer shape of the heatsink. At least two beam-shifting structures are positioned in a beam path of each of the plurality of single emitter diodes, the at least two beam-shifting structures folding each beam emitted from the plurality of single emitter diodes in at least three dimensions. At least one beam combining structure is positioned in the beam path, wherein the at least one beam combining structure combines the beams from each of the plurality of single emitter diodes into a single, combined beam. At least one output is provided, from which the single, combined beam is output from the ultra-compact, high power, fiber pump module apparatus.

The present disclosure can also be viewed as providing a method of cooling an ultra-compact, high power, fiber pump module. In this regard, one embodiment of such a method, among others, can be broadly summarized by the following steps: providing a heatsink having a stepped outer shape, the heatsink having at least one interior cooling channel; positioning a plurality of single emitter diodes on the heatsink, wherein each of the plurality of single emitter diodes is positioned on one step of the stepped outer shape of the heatsink; emitting a quantity of light from at least a portion of the plurality of single emitter diodes, wherein the quantity of light follows a beam path; folding the beam path in at least three dimensions with at least two beam-shifting structures positioned in the beam path of each of the plurality of single emitter diodes; combining beams from each of the plurality of single emitter diodes into a single, combined beam with at least one beam combining structure positioned in the beam path; and outputting the combined beam from the ultra-compact, high power, fiber pump module.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

The patent or application file contains at least one drawing executed in color. Copies of this patent or patent application publication with color drawing(s) will be provided by the Office upon request and payment of the necessary fee.

FIG. 1 is an illustration of a layout of a single emitter pump module, in accordance with the prior art.

FIG. 2 is an illustration of a light path diagram showing the path of the light in the module, in accordance with the prior art.

FIG. 3 is an isometric view illustration of an ultra-compact, high power, fiber pump module, in accordance with a first exemplary embodiment of the present disclosure.

FIG. 4 is back, side view illustration of the ultra-compact, high power, fiber pump module of FIG. 3, in accordance with the first exemplary embodiment of the present disclosure.

FIG. 5 is top view illustration of the ultra-compact, high power, fiber pump module of FIG. 3, in accordance with the first exemplary embodiment of the present disclosure.

FIG. 6 is rear view illustration of the ultra-compact, high power, fiber pump module of FIG. 3, in accordance with the first exemplary embodiment of the present disclosure.

FIGS. 7-8 are illustrations of the beam path of the ultra-compact, high power, fiber pump module of FIGS. 2-6, in accordance with the first exemplary embodiment of the present disclosure.

FIGS. 9-11 are illustrations of the beam output, in accordance with the first exemplary embodiment of the present disclosure.

FIGS. 12-13 are illustrations of the heatsink used with the ultra-compact, high power, fiber pump module of FIGS. 2-6, in accordance with the first exemplary embodiment of the present disclosure.

FIG. 14 is a cross sectional illustration of the heatsink used with the ultra-compact, high power, fiber pump module of FIGS. 2-6, and in particular, showing the cooling channels, in accordance with the first exemplary embodiment of the present disclosure.

FIG. 15 is a flowchart illustrating a method of cooling an ultra-compact, high power, fiber pump module, in accordance with the first exemplary embodiment of the disclosure.

### DETAILED DESCRIPTION

With modern optical technology, there is a demand for higher power per module, which can only be achieved by increasing the footprint of existing modules proportionally. However, when the footprint is increased, contact cooling is no longer sufficient to cool modules with power levels greater than 400W. To provide a solution, the subject disclosure is directed to an ultra-compact, high power, fiber pump module which is a single-emitter module with a smaller footprint and module weight, which adds more efficient cooling capabilities to allow power levels above 400W per module, and preferably, above 500W per module. In accordance with this disclosure, the term ‘high power’ can be understood as being power levels above 400W.

The ultra-compact, high power, fiber pump module is built using the similar components as conventional modules, in that, the ultra-compact, high power, fiber pump module includes a chip on submount (COS) design, fast-axis collimator (FAC) lenses to collimate the beam in one direction, second-axis collimator (SAC) lenses to collimate the beam in a second direction, mirror arrangements to optically stack the beams, and various prisms and lenses to combine the beams or refine the beams. Unlike conventional single emitter modules, however, these components in the ultra-compact, high power, fiber pump module are arranged in a unique and space-saving design, which allows for the beam to travel in a three-dimensional (3D) space, and still permits them to be coupled efficiently into a fiber optic line. Despite this 3D space, cooling of the ultra-compact, high power, fiber pump module is optimized by an integrated approach for improved water cooling. Additionally, the cooling platform and beam propagation are folded to minimize size and decrease the weight of the ultra-compact, high power, fiber pump module.

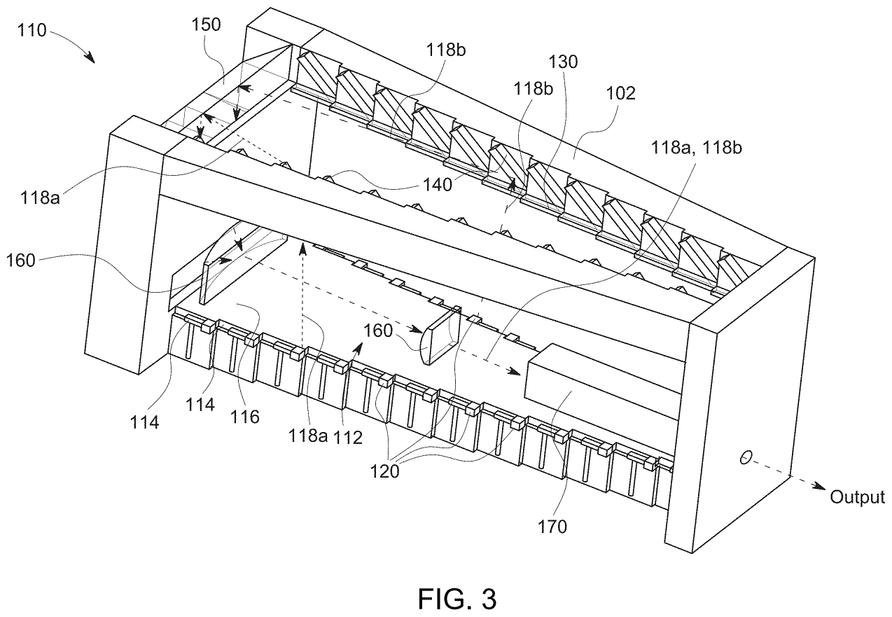

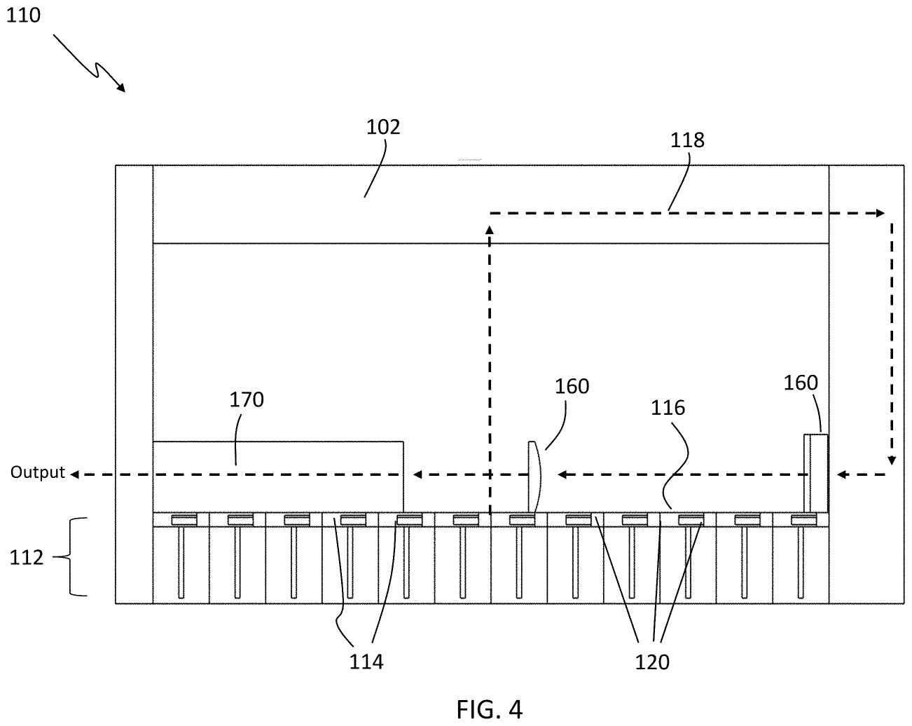

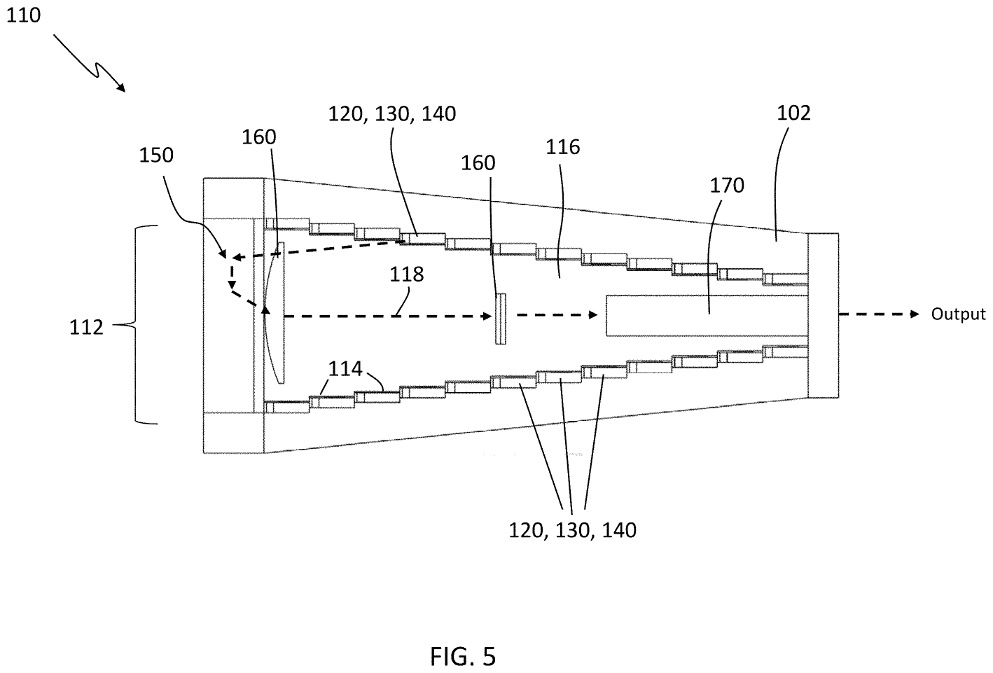

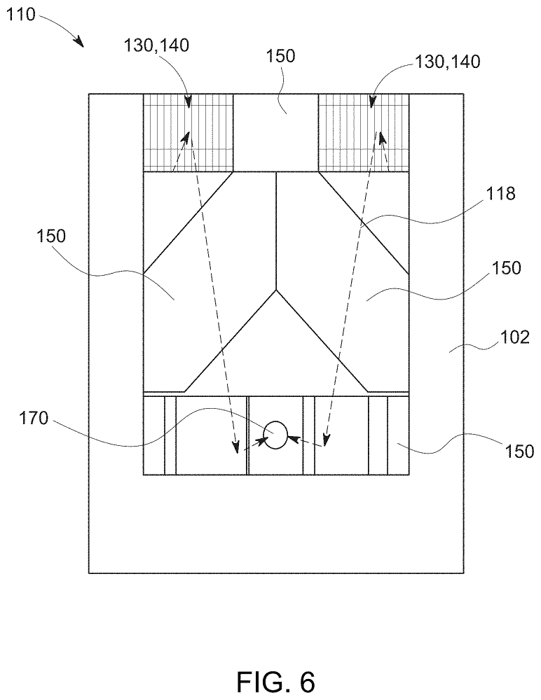

FIG. 3 is an isometric view illustration of an ultra-compact, high power, fiber pump module 110, in accordance with a first exemplary embodiment of the present disclosure. Similarly, FIG. 4 is a back, side view illustration of the ultra-compact, high power, fiber pump module 110, FIG. 5 is a top view illustration of the ultra-compact, high power, fiber pump module 110, and FIG. 6 is a rear view illustration of the ultra-compact, high power, fiber pump module 110. With reference to FIGS. 3-6, the ultra-compact, high power, fiber pump module 110, which may be referred to herein simply as ‘module 110,’ includes a plurality of single emitter laser diodes 120 which are positioned on both side edges of a stepped heatsink 112. The stepped heatsink 112 has an elongated design which narrows at one end, with steps or stepped features 114 on both sides thereof, such that each of the single emitter diodes 120 is mounted to one of the stepped features 114 and each step or each of the single emitter diodes 120 is positioned a different linear distance to a center of the stepped heatsink 112 than other single emitter diodes 120 on the same side. With this design, each of the single emitter diodes 120 is positioned on a separate stepped face of the heatsink 112, whereby single emitter diodes 120 are able to be spread across the stepped face of the heatsink 112 on both sides of the heatsink 112 for optically stacking the beams. In one example, the stepped features 114 may be approximately 0.4-1 mm but other dimensions are possible.

The single emitter diodes 120 are oriented to direct their light path 118 in a direction perpendicular with the planar top face 116 of the stepped heatsink 112. An exemplary depiction for the single emitter diodes 120 positioned in the front of FIG. 3 has a light path 118a which is illustrated with small dash-dash broken lines, while an exemplary depiction of the light path 118b of the single emitter diodes 120 positioned in the rear of FIG. 3 is illustrated with large dash-dash broken lines. As shown, the light paths 118a, 118b are directed from the single emitter diode 120 towards lenses 130 which are positioned proximate to mirrors 140, or similar beam-shifting or folding structures, both of which are mounted on a framework 102 of the ultra-compact, high power, fiber pump module 110. The framework 102 is positioned generally on forward and rear ends of the heatsink 112 and extends upwards on either side of the heatsink 112, such that each of the lenses 130 and mirrors 140 are able to be located on the framework 102 in a position within the light path of the single emitter diodes 120. In FIG. 3, this position is substantially above each of the single emitter diodes 120.

At the point of the mirrors 140, the light paths 118a, 118b are folded over or directed towards the rear end of the heatsink 112, e.g., substantially perpendicular to the direction of the light paths 118a, 118b between the single emitter diodes 120 and the mirrors 140, and into one or more beam-combining structures 150, such as a polarization prism. The beam-combining structures 150 may be used to eliminate a gap within the beams. At the beam-combining structures 150, the light paths 118a, 118b of the beam are folded again in a direction towards the planar top surface 116 of the heatsink 112, but in a location offset from the rear end of the heatsink 112. For instance, the direction of folding here is substantially perpendicular to the path direction between the mirror 140 and the beam-combining structures 150, and substantially parallel to the first direction, the direction of the light paths 118a, 118b between the single emitter diodes 120 and the mirrors 140, and into one or more beam-combining structures 150. At a location above the planar top surface 116 of the heatsink 112, the light paths 118a, 118b are then bent one more time in a direction substantially parallel with the planar top surface 116. In this direction, the light paths 118a, 118b are substantially perpendicular to the third direction from the beam-combining structures 150, and substantially parallel to the second direction from the mirror 140 to the beam-combining structures 150. In this direction, the light paths 118a, 118b can travel through one or more lenses 160 and is then output into a fiber optic cable positioned at least partially within a fiber optic housing 170 integrated into the heatsink 112.

As can be understood, the beams from the COS on both sides of the heatsink 112 are collimated with two or more lenses per COS and arranged as optical stack with individual mirrors, as shown in FIG. 3, for example. Thus, each side of the heatsink 112 is capable of delivering a stack of beams which can be combined in several ways, such as with polarization coupling, beam shifting, or expanding the individual stacked beams to reduce the gap between the stacked beams. The beams will be folded back with beam-combining or shifting devices, such as mirrors or prisms, and into the empty space between the heatsink 112 and the mirror arrangement. The heatsink 112 may be used as an optical bench for the focusing lenses and the fiber optic cable.

As shown in detail in FIGS. 3-5, the light path, generally denoted at 118, from each of the single emitter diodes 120 moves in a substantially three-dimensional (3D) path, whereby the light moves in a first direction between the single emitter diode 120 and the mirror 140, e.g., along the height of the module 110, then moves in a second direction towards the beam-combining structures 150, e.g., along a length of the module 110, whereby the light path 118 moves inwards towards the center of the module 110, e.g., along a width of the module 110. The light path 118 is then folded in another direction towards the heatsink 112, and then is folded in yet another direction parallel with the heatsink 112 until it is output. The light path 118 is depicted in medium-sized dash-dash broken lines within FIGS. 4-6.

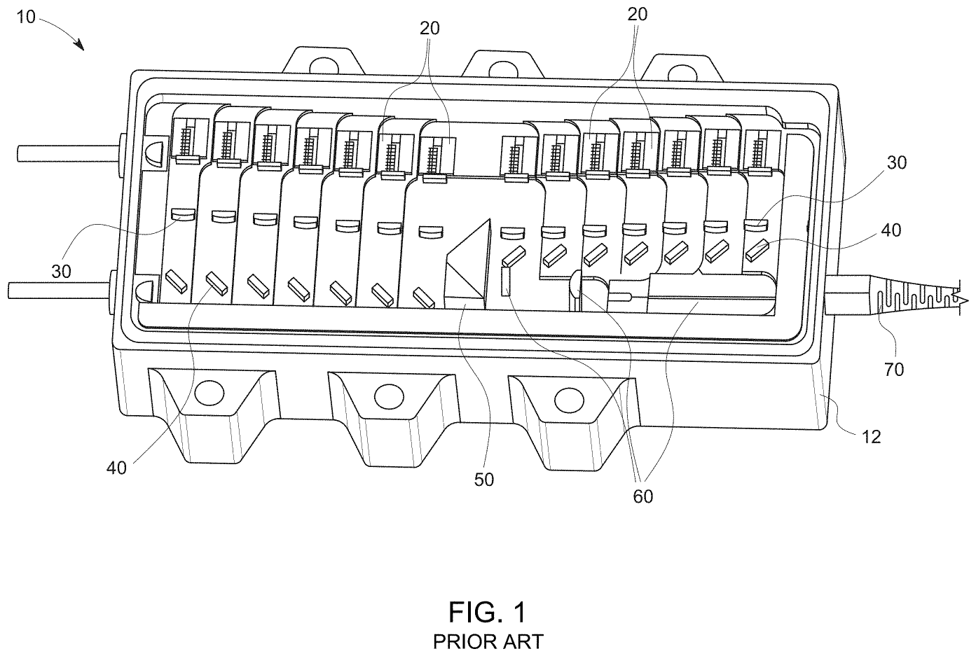

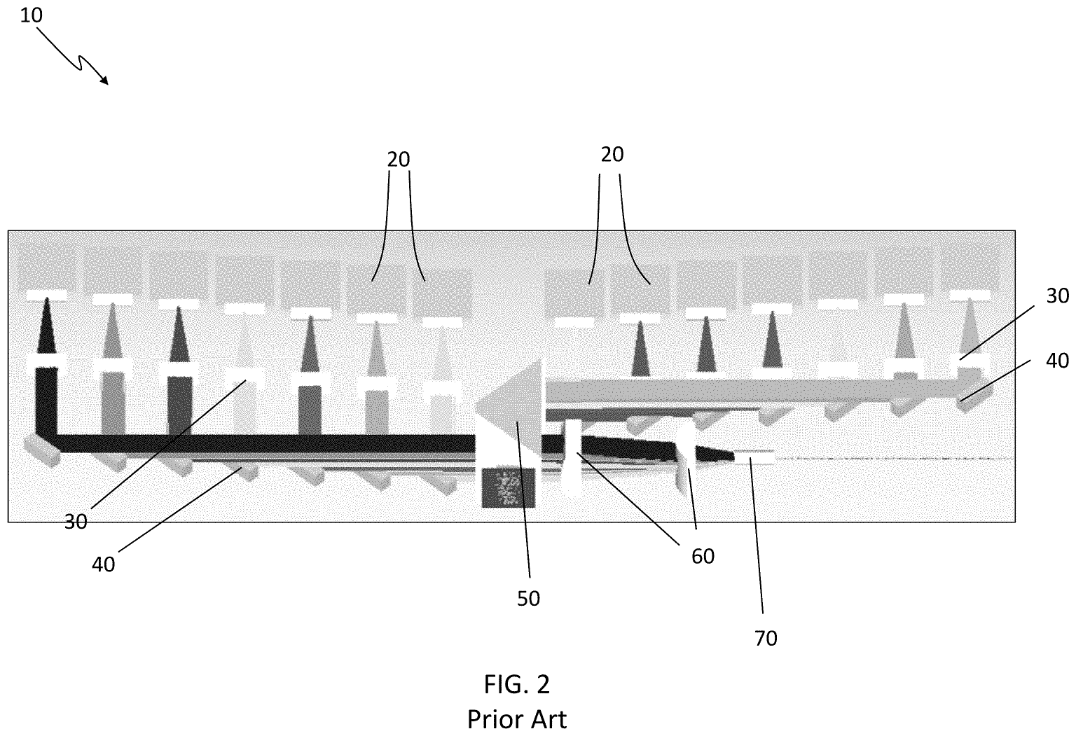

This 3D light path 118 is unlike conventional modules, as discussed relative to FIGS. 1-2, where the light path 118 travels in only a planar or two-dimensional (2D) space. In FIGS. 5-6, the 3D light path 118 can also be seen, in particular from the rear view shown in FIG. 6. As can be seen, when the beam is transmitted from the mirrors 140, it is moved downwards and inwards with the beam-combining structures 150 positioned along the backside of the module 110, and then the beam is folded into the fiber optic cable.

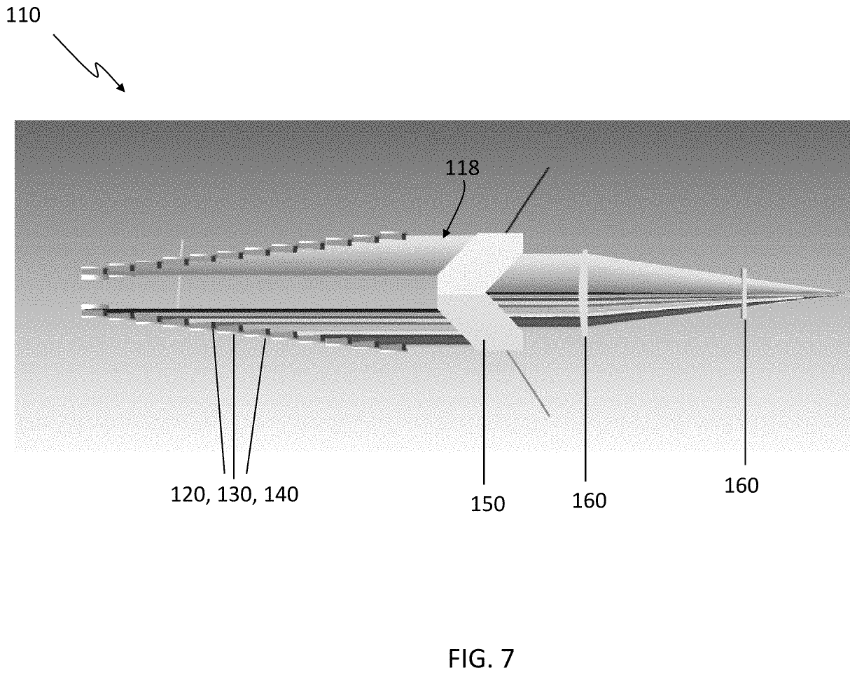

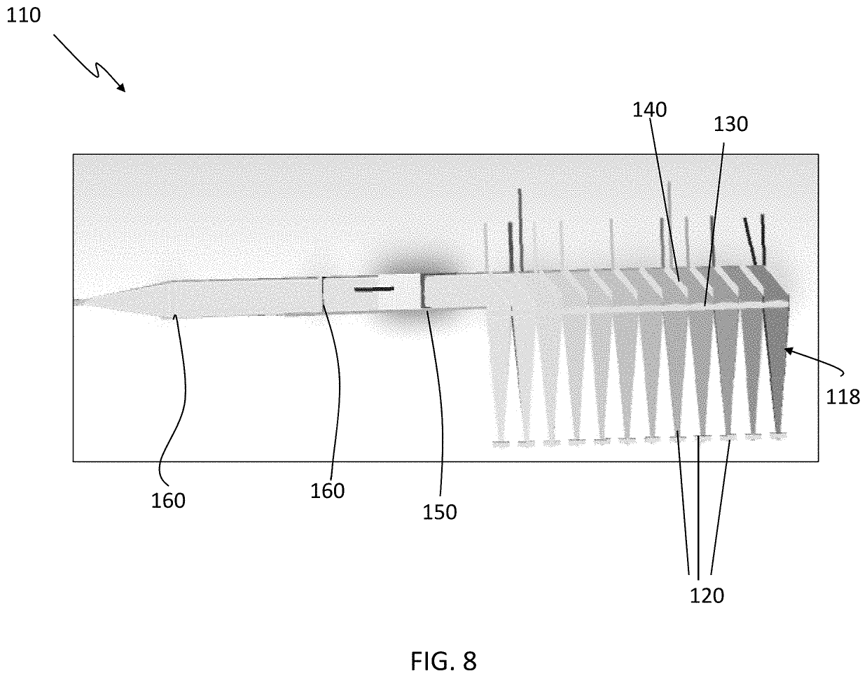

FIGS. 7-8 are illustrations of the various light paths 118 of the ultra-compact, high power, fiber pump module 110 of FIGS. 2-6, in accordance with the first exemplary embodiment of the present disclosure. In particular, FIG. 7 illustrates a top view of the beam path, while FIG. 8 illustrates a side view of the beam path. As shown in both FIGS. 7-8, the light path 118 originates at the single emitter diodes 120, and moves in a first direction towards the lenses 130 and mirrors 140. The light path 118 then turns substantially perpendicular to move in a second direction into one or more beam-combining structures 150. The light path 118 turns at least once more to move in a third direction, where it moves through one or more lenses 160. The differently colored light paths 118 in FIGS. 7-8 represent the different individual light paths for each of the single emitters 120.

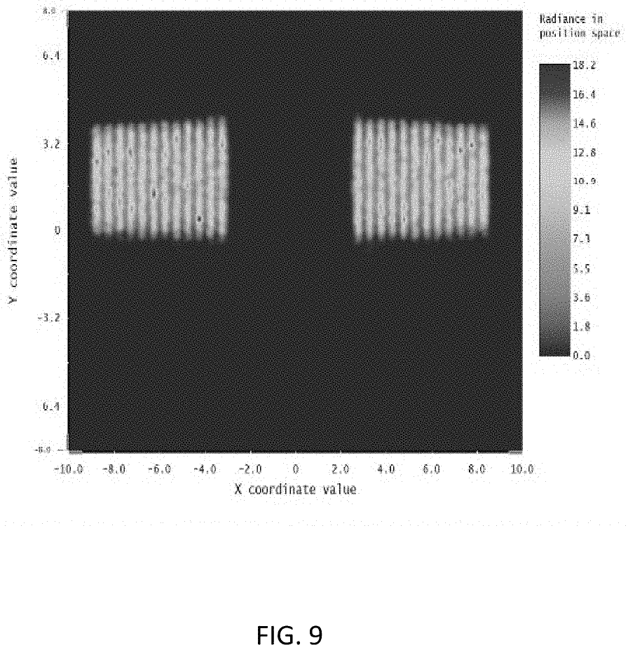

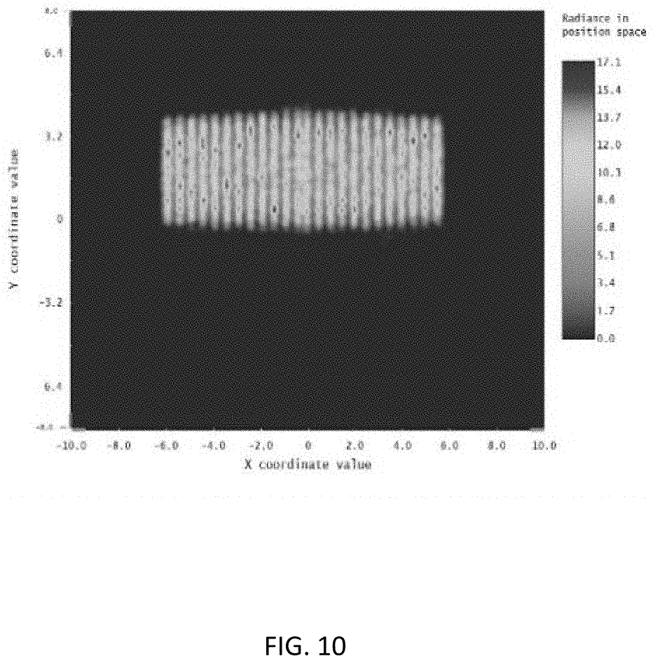

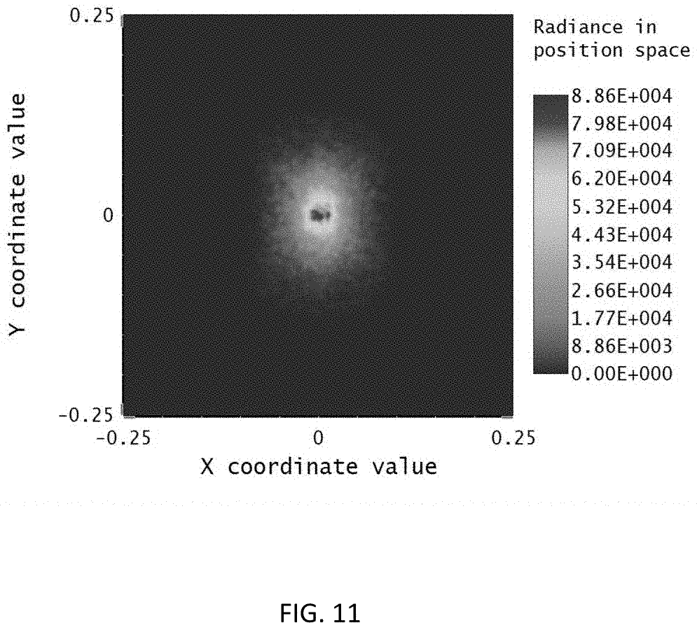

FIGS. 9-11 are illustrations of the beam output of the light path, in accordance with the first exemplary embodiment of the present disclosure. Specifically, FIGS. 9-10 depict the radiance in position space with 99% of the beam before the fiber optic cable. As shown in FIG. 9, the beam is substantially divided into two separate groups, one on the left and one on the right, while FIG. 10 illustrates the two groups being moved close to one another, such that the groups are positioned next to each other, whereby the left and right formations do not have a space therebetween. Then, FIG. 11 depicts the radiance in position space with 98% in the fiber optic cable. This is the situation where the two groups are moved into a single spot or point. FIGS. 9-11 illustrate the intensity profile of the beam in color, with the intensity level corresponding to the color key shown in the figures.

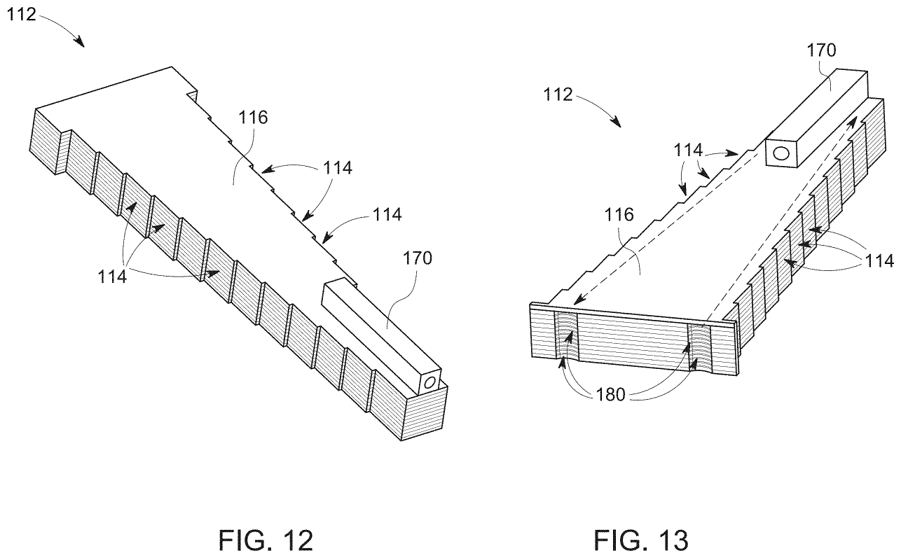

FIGS. 12-13 are illustrations of the heatsink 112 used with the ultra-compact, high power, fiber pump module 110 of FIGS. 3-6, in accordance with the first exemplary embodiment of the present disclosure. As shown, the heatsink 112 has a substantially planar top surface 116 with sidewalls which have stepped features 114 on which the single emitter diodes (FIGS. 3-6) are positioned. As shown, the heatsink 112 has integrated within it a fiber optic housing 170 which receives the end of the fiber optic cable (not shown) in which the combined beams are output to. Since the fiber optic housing 170 is integrated into the heatsink 112, it can be cooled with the water cooling features of the heatsink 112. The heatsink 112 may be constructed out of single foils which are half etched. For instance, in one example, the heatsink 112 is constructed using twelve (12) half etched copper foils having a thickness of approximately 0.5 mm, which are machined to generate a step size of approximately 0.5 mm for the single emitter diodes 120 generating the optically stacked beams.

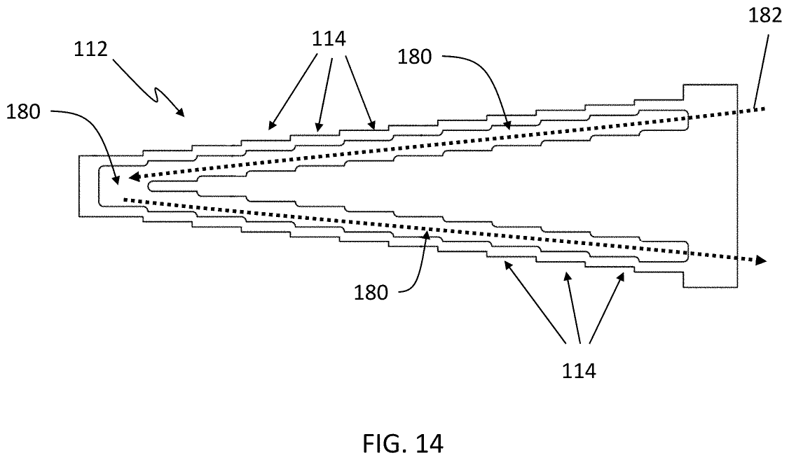

The heatsink 112 has integrated cooling into its structure, which makes it highly efficient. In particular, there are a plurality of cooling channels 180 positioned within the heatsink 112 which generally follow the footprint outline of the heatsink 112. FIG. 14 is a cross sectional illustration of the heatsink 112 used with the ultra-compact, high power, fiber pump module 110 of FIGS. 3-6, and in particular, showing the cooling channels 180, in accordance with the first exemplary embodiment of the present disclosure. As shown in FIGS. 12-14, the plurality of cooling channels 180 may have an inlet and outlet along a backside of the heatsink 112, such that the path 182 of the cooling fluid, which is indicated by the small dash-dash broken lines, can traverse down one side of the heatsink 112 and traverse back along the opposing side of the heatsink 112.

As can be seen, the cooling channels 180 forming the cooling path 182 are positioned adjacent to the stepped features 114 on which the single emitter diodes are positioned, such that they can effectively cool the single emitter diodes. Additionally, the cooling channels 180 are positioned to run underneath and proximate to the fiber optic housing 170, such that heat generated therein can be dissipated throughout the heatsink 112 and the cooling fluid within the channels 180, which provides integrated cooling for the fiber connector and the fiber optic cable. Because there is a large cooling area provided by the cooling channels 180, it enables the ultra-compact high power fiber pump module 110 to achieve more efficient cooling than conventional systems.

In comparison to current or conventional laser modules, the ultra-compact high power fiber pump module 110 of this disclosure provides significant improvements. For instance, the cooling platform formed by the heatsink 112 is capable of providing improved cooling performance at or substantially approximate to two times that of conventional modules. This improved cooling may allow closer contact of the semiconductor to the cooling fluid, which enables thermal impedance values below 1.5K/W per COS. In contrast, typical values within conventional single emitter modules are on the order of 2-3 K/W. Additionally, since the heatsink 112 can have single emitter diodes positioned on the steps of both sides thereof, the emitted light is arranged perpendicular to the mounting surface (footprint) of the heatsink 112. This reduces the COS footprint by a factor of 10x compared to conventional single emitter diodes, such that the ultra-compact high power fiber pump module 110 can achieve a COS per module of 14 to 30 in the same space a conventional module can only achieve a fraction of that number.

As an example of the more compact size of the ultra-compact high power fiber pump module 110 relative to conventional modules, a typical conventional module commonly has a footprint, i.e., width by length, of 30 mm by 105 mm. Within this space, the conventional module may include 14-20 single emitter diodes. The ultra-compact high power fiber pump module 110, however, can fit 14-30 diodes within a footprint that is near half that size, such as a size of 20 mm wide by 65 mm long. The ability for the ultra-compact high power fiber pump module 110 to achieve this more compact size is due to the ability for the beams to be folded in a 3D shape. For instance, the height of the ultra-compact high power fiber pump module 110, as measured from the heatsink 112 to the mirrors 140, as shown in FIG. 3, may be approximately 30 mm in this example. These dimensions are exemplary and the actual dimensions of the ultra-compact high power fiber pump module 110 can vary depending on the design and the implementation of the device. In other examples, it is possible to reduce the footprint, size, and weight of the module by as much as four times relative to comparable conventional modules.

It is noted that while the ultra-compact high power fiber pump module 110 provides significant benefits with high power modules, it is also possible to use the ultra-compact high power fiber pump module 110 in situations with less than 400W. For instance, the ultra-compact high power fiber pump module 110 can still provide a significant reduction in the footprint and size of the module relative to those currently used. Thus, even when lower powered systems are required, the ultra-compact high power fiber pump module 110 may still provide benefits. It is also noted that the ultra-compact high power fiber pump module 110 can be used for applications outside of fiber coupling, such as where a compact, highly collimated beam is desired.

Implementation of the ultra-compact high power fiber pump module 110 can vary, but in one primary example, it will be implemented in a fiber pump module having power level greater than 400W, and more preferably, greater than 500W, using a total of 24 COS with 220 um emitter to be coupled into a 225 um optical fiber with 0.22 NA. The heatsink will be established by using 12 half etched copper foils (0.5 mm thick) and machined to generate a step size of 0.5 mm for the optically stacked beams.

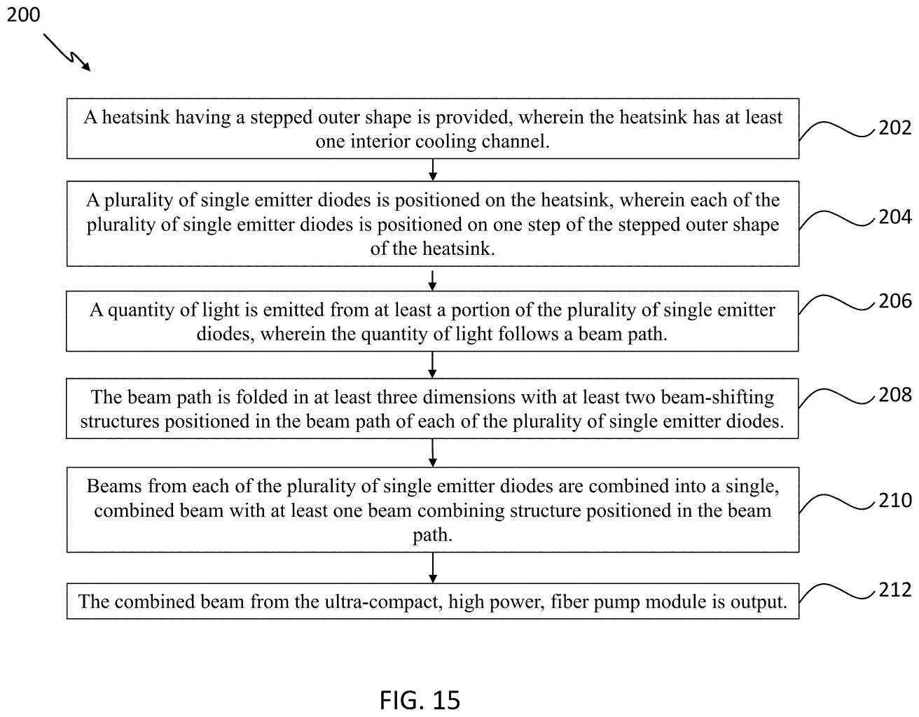

FIG. 15 is a flowchart 200 illustrating a method of cooling an ultra-compact, high power, fiber pump module, in accordance with the first exemplary embodiment of the disclosure. It should be noted that any process descriptions or blocks in flow charts should be understood as representing modules, segments, portions of code, or steps that include one or more instructions for implementing specific logical functions in the process, and alternate implementations are included within the scope of the present disclosure in which functions may be executed out of order from that shown or discussed, including substantially concurrently or in reverse order, depending on the functionality involved, as would be understood by those reasonably skilled in the art of the present disclosure.

As is shown by block 202, a heatsink having a stepped outer shape is provided, wherein the heatsink has at least one interior cooling channel. A plurality of single emitter diodes is positioned on the heatsink, wherein each of the plurality of single emitter diodes is positioned on one step of the stepped outer shape of the heatsink (block 204). A quantity of light is emitted from at least a portion of the plurality of single emitter diodes, wherein the quantity of light follows a beam path (block 206). The beam path is folded in at least three dimensions with at least two beam-shifting structures positioned in the beam path of each of the plurality of single emitter diodes (block 208). Beams from each of the plurality of single emitter diodes are combined into a single, combined beam with at least one beam combining structure positioned in the beam path (block 210). The combined beam from the ultra-compact, high power, fiber pump module is output (block 212). Any number of additional steps, functions, processes, or variants thereof may be included in the method, including any disclosed relative to any other figure of this disclosure.

It should be noted that any process descriptions or blocks in flow charts should be understood as representing modules, segments, portions of code, or steps that include one or more instructions for implementing specific logical functions in the process, and alternate implementations are included within the scope of the present disclosure in which functions may be executed out of order from that shown or discussed, including substantially concurrently or in reverse order, depending on the functionality involved, as would be understood by those reasonably skilled in the art of the present disclosure.

It should be emphasized that the above-described embodiments of the present disclosure, particularly, any “preferred” embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. An ultra-compact, high power, fiber pump module apparatus comprising:
a heatsink having a stepped outer shape, the heatsink having at least one interior cooling channel;
at least one single emitter diode positioned on one step of the stepped outer shape of the heatsink;
at least two beam-shifting structures positioned in a beam path of the at least one single emitter diode, the at least two beam-shifting structures folding a beam emitted from the at least one single emitter diode in at least three dimensions; and
at least one output with which the beam is output from the ultra-compact, high power, fiber pump module apparatus.

2. The apparatus of claim 1, wherein the stepped outer shape narrows at one end, wherein steps are positioned on both sides of the stepped outer shape, and wherein each of the steps are positioned a different linear distance to a center of the stepped heatsink.

3. The apparatus of claim 1, wherein the at least two beam-shifting structures positioned in the beam path of the at least one single emitter diode comprises:
at least one first lens and mirror, positioned to receive the beam from the at least one single emitter diode and fold the beam from a first direction to a second direction, wherein the second direction is substantially perpendicular to the first direction;
at least one beam-combining structure positioned to receive the beam from the first lens and mirror and fold the beam from the second direction to at least a third direction, wherein the third direction is substantially perpendicular to the second direction and substantially parallel to the first direction; and
at least one second lens positioned to receive the beam from the beam-combining structure and fold the beam from the third direction to a fourth direction, wherein the fourth direction is substantially perpendicular to the third direction and substantially parallel to the second direction.

4. The apparatus of claim 3, wherein the beam-combining structure further comprises a polarization prism.

5. The apparatus of claim 1, wherein the heatsink further comprises twelve half etched copper foils.

6. The apparatus of claim 1, wherein the at least one interior cooling channel is positioned adjacent to the step on which the single emitter diode is positioned.

7. The apparatus of claim 1, wherein the single emitter diode is positioned to direct the beam path in a direction perpendicular with a planar top face of the heatsink.

8. An ultra-compact, high power, fiber pump module apparatus comprising:
a heatsink having a stepped outer shape, the heatsink having at least one interior cooling channel;
a plurality of single emitter diodes, each positioned on one step of the stepped outer shape of the heatsink;
at least two beam-shifting structures positioned in a beam path of each of the plurality of single emitter diodes, the at least two beam-shifting structures folding each beam emitted from the plurality of single emitter diodes in at least three dimensions;
at least one beam combining structure positioned in the beam path, wherein the at least one beam combining structure combines the beams from each of the plurality of single emitter diodes into a single, combined beam; and
at least one output with which the single, combined beam is output from the ultra-compact, high power, fiber pump module apparatus.

9. The apparatus of claim 8, wherein the stepped outer shape narrows at one end, wherein steps are positioned on both sides of the stepped outer shape, and wherein each of the steps are positioned a different linear distance to a center of the stepped heatsink.

10. The apparatus of claim 8, wherein the at least two beam-shifting structures positioned in the beam path of the plurality of emitter diodes comprises:
at least one first lens and mirror, positioned to receive the beam from each of the plurality of single emitter diodes and fold the beam from a first direction to a second direction, wherein the second direction is substantially perpendicular to the first direction;
at least one beam-combining structure positioned to receive the beam from the first lens and mirror and fold the beam from the second direction to at least a third direction, wherein the third direction is substantially perpendicular to the second direction and substantially parallel to the first direction; and
at least one second lens positioned to receive the beam from the beam-combining structure and fold the beam from the third direction to a fourth direction, wherein the fourth direction is substantially perpendicular to the third direction and substantially parallel to the second direction.

11. The apparatus of claim 10, wherein the beam-combining structure further comprises a polarization prism.

12. The apparatus of claim 8, wherein the heatsink further comprises twelve half etched copper foils.

13. The apparatus of claim 8, wherein the at least one interior cooling channel is positioned adjacent to the step on which the plurality of single emitter diodes is positioned.

14. The apparatus of claim 8, wherein the plurality of single emitter diodes is positioned to direct the beam path in a direction perpendicular with a planar top face of the heatsink.

15. A method of cooling an ultra-compact, high power, fiber pump module, the method comprising:
providing a heatsink having a stepped outer shape, the heatsink having at least one interior cooling channel;
positioning a plurality of single emitter diodes on the heatsink, wherein each of the plurality of single emitter diodes is positioned on one step of the stepped outer shape of the heatsink;
emitting a quantity of light from at least a portion of the plurality of single emitter diodes, wherein the quantity of light follows a beam path;
folding the beam path in at least three dimensions with at least two beam-shifting structures positioned in the beam path of each of the plurality of single emitter diodes;
combining beams from each of the plurality of single emitter diodes into a single, combined beam with at least one beam combining structure positioned in the beam path; and
outputting the combined beam from the ultra-compact, high power, fiber pump module.

16. The method of claim 15, wherein the stepped outer shape narrows at one end, wherein steps are positioned on both sides of the stepped outer shape, and wherein each of the steps are positioned a different linear distance to a center of the stepped heatsink.

17. The method of claim 15, wherein the at least two beam-shifting structures positioned in the beam path of the plurality of emitter diodes comprises:
at least one first lens and mirror receiving the beam from each of the plurality of single emitter diodes and folding the beam from a first direction to a second direction, wherein the second direction is substantially perpendicular to the first direction;
at least one beam-combining structure receiving the beam from the first lens and mirror and folding the beam from the second direction to at least a third direction, wherein the third direction is substantially perpendicular to the second direction and substantially parallel to the first direction; and
at least one second lens receiving the beam from the beam-combining structure and folding the beam from the third direction to a fourth direction, wherein the fourth direction is substantially perpendicular to the third direction and substantially parallel to the second direction.

18. The method of claim 15, wherein the heatsink further comprises twelve half etched copper foils.

19. The method of claim 15, wherein the at least one interior cooling channel is positioned adjacent to the step on which the plurality of single emitter diodes is positioned.

20. The method of claim 15, wherein the plurality of single emitter diodes is positioned to direct the beam path in a direction perpendicular with a planar top face of the heatsink.
